(19) United States
(12) Patent Application Publication
(10) Pub. No.: US 2021/0251104 A1
(43) Pub. Date: Aug. 12, 2021

(54) HEAT RADIATING DEVICE

(71) Applicant: Panasonic Intellectual Property Management Co., Ltd., Osaka (JP)

(72) Inventors: Takashi MITSUNARI, Fukuoka (JP); Kenichi NAKANO, Fukuoka (JP); Katsuya SAKAMOTO, Mie (JP); Youhei MINESAKI, Fukuoka (JP); Yoshitada HIGASHIMOTO, Fukuoka (JP)

(73) Assignee: Panasonic Intellectual Property Management Co., Ltd., Osaka (JP)

(21) Appl. No.: 16/973,982

(22) PCT Filed: May 31, 2019
(86) PCT No.: PCT/JP2019/021709

§ 371 Date: Dec. 10, 2020

(30) Foreign Application Priority Data
Jun. 11, 2018 (JP) 2018-111089
Dec. 18, 2018 (JP) 2018-236218
Feb. 25, 2019 (JP) 2019-031813

(51) Int. Cl. H05K 7/20

(52) U.S. Cl. CPC H05K 7/20154

(57) ABSTRACT

This heat radiating device is provided with a heat radiating part for radiating the heat of a heat generating body, and a fan provided on a surface opposite to a surface on which the heat generating body of the heat radiating part is located. The heat radiating part is formed by stacking a plurality of plate-like heat radiating plates, and comb-like fin parts that extend radially in the in-plane direction are formed on the peripheries of the respective heat radiating plates.

### TECHNICAL FIELD

The present disclosure relates to a heat radiating device that dissipates heat from a heating element of an electronic device.

### BACKGROUND ART

A heat radiating device that cools a central processing unit (CPU) of a personal computer or the like has been known (see, e.g., Patent Literature (hereinafter, referred to as PTL) 1). Such a heat radiating device has a heat sink disposed on the CPU and a cooling fan disposed on the heat sink.

### CITATION LIST

### Patent Literature

### PTL 1

Japanese Patent Application Laid-Open No. 2014-183284

### SUMMARY OF INVENTION

### Technical Problem

A heat radiating device can improve the cooling performance by increasing the size of a heat sink or increasing the rotation speed of a fan.

However, increasing the size of a heat sink disadvantageously increases the size of the entire device, and increasing the rotation speed of a fan also disadvantageously increases noise.

Non-limiting examples of the present disclosure facilitate providing a small heat radiating device with high cooling performance.

### Solution to Problem

A heat radiating device according to one aspect of the present disclosure includes a heat radiator that dissipates heat of a heating element; and a fan provided on or above a surface of the heat radiator, the surface being opposite to another surface where the heating element is located, in which the heat radiator is formed by stacking a plurality of heat radiating plates having a plate shape, and a fin extending radially in an in-plane direction is formed at a periphery of each of the plurality of heat radiating plates, the fin having a comb shape.

It should be noted that general or specific embodiments may be implemented as a system, a method, an integrated circuit, a computer program, or a storage medium, or any selective combination of a system, an apparatus, a method, an integrated circuit, a computer program, and a storage medium.

### Advantageous Effects of Invention

One aspect of the present disclosure can achieve a small size and high cooling performance.

Additional benefits and advantages of one aspect of the present disclosure will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF DRAWINGS

FIG. 1 is a perspective view illustrating an example of a heat radiating device according to the first embodiment;

FIG. 2 is a side view illustrating an example of the heat radiating device;

FIG. 3 is a cross-sectional view of the heat radiating device taken along arrows A-A of FIG. 1;

FIG. 4 is an exploded perspective view illustrating an example of the heat radiating device;

FIG. 5 is a perspective view illustrating an example of a heat radiating plate;

FIG. 6 is a perspective view illustrating an example of a heat radiating plate;

FIG. 7A is a diagram for explaining an example of a method for manufacturing the heat radiating device;

FIG. 7B is a diagram for explaining the example of the method for manufacturing the heat radiating device;

FIG. 7C is a diagram for explaining the example of the method for manufacturing the heat radiating device;

FIG. 7D is a diagram for explaining the example of the method for manufacturing the heat radiating device;

FIG. 8A is a perspective view illustrating a part of a heat radiator;

FIG. 8B is a perspective view illustrating a part of the heat radiator;

FIG. 9 is a diagram for explaining an example of a method for fixing the heat radiating plates according to the second embodiment;

FIG. 10 is a perspective view illustrating a cross-section taken along arrows A-A of FIG. 9;

FIG. 11 is a front view of the heat radiating plates of FIG. 10;

FIG. 12 illustrates the heat radiating plates stacked;

FIG. 13 is an enlarged view of a portion shown by the dotted line frame B in FIG. 12;

FIG. 14 is a diagram for explaining the heat conduction of the heat radiating plates;

FIG. 15 is a diagram for explaining exemplary dimensions of a heat radiating plate;

FIG. 16 is a diagram for explaining the difference between the case where heat radiating plates are fixed by caulking and the case where the heat radiating plates are fixed by screws;

FIG. 17 is a diagram for explaining the positions of protrusions and depressions formed in extension plate sections;

FIG. 18 is a diagram for explaining the positions of protrusions and depressions formed in extension plate sections;

FIG. 19 is an exploded perspective view of a heat radiating device according to the third embodiment;

FIG. 20 is a cross-sectional perspective view of a heat radiator and a frame;

FIG. 21 is a side view of the heat radiating device;

FIG. 22 is a partial cross-sectional view of the heat radiating device;

FIG. 23 is a diagram for explaining the air volume of a heat radiating device;

FIG. 24 is a diagram for explaining the air volume of the heat radiating device;

FIG. 25 is a diagram for explaining the air volume of the heat radiating device;

FIG. 26 shows the thermal resistance evaluation of the heat radiating device;

FIG. 27 shows the thermal resistance evaluation of the heat radiating device;

FIG. 28 is a side view of the heat radiating device; and

FIG. 29 is a side view of the heat radiating device.

### DESCRIPTION OF EMBODIMENTS

Embodiments of the present invention will be described below in detail with reference to the accompanying drawings as appropriate. It is, however, noted that a description made in detail more than necessary is omitted in some cases. For example, a detailed description of an already well-known item and a duplicate description of substantially the same configuration are omitted in some cases. The reason for this is to prevent the following description from being unnecessarily redundant and allow a person skilled in the art to readily understand the present disclosure.

The accompanying drawings and the following descriptions are provided to allow a person skilled in the art to fully understand the present disclosure and are not intended to limit the subject set forth in the appended claims.

Automobiles are equipped with various electronic devices mounted thereon. For example, an automobile is equipped with electronic devices such as an engine control unit (ECU), a head-up display (HUD), an advanced driver-assistance system (ADAS), a digital meter cluster, a drive circuit of a headlamp light emitting diode (LED) and a car navigation system.

These electronic devices include, for example, a heating element such as a CPU or a system-on-a-chip (SOC). For reducing the occurrence of malfunction of the electronic devices, it is important to dissipate heat of the CPU, SOC or the like by a heat radiating device.

Electronic devices mounted in automobiles are required to be small and quiet depending on, for example, the installation location. For example, a digital meter cluster is disposed in front of a driver, and thus it is important to reduce noise of a fan of a heat radiating device so that the driver cannot hear the noise. It is thus important that the heat radiating device is small and can sufficiently dissipate heat from a heating element without rotating the fan at high speed.

### First Embodiment

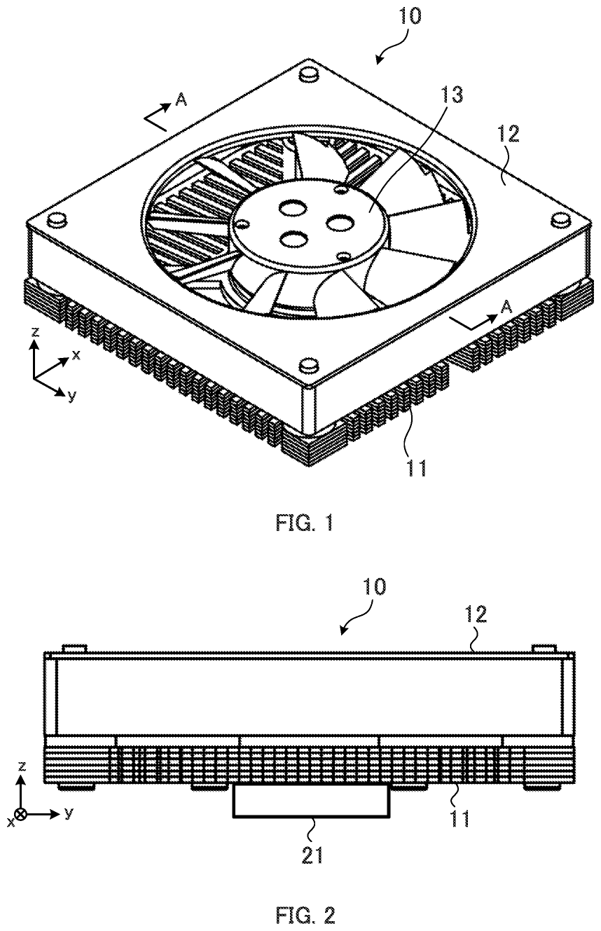

FIG. 1 is a perspective view illustrating an example of heat radiating device 10 according to the first embodiment. As illustrated in FIG. 1, heat radiating device 10 includes heat radiator 11, frame 12 and fan 13. Heat radiator 11, frame 12 and fan 13 are integrated. In the following, the x, y, and z axes of the three axes illustrated in FIG. 1 are set with respect to heat radiating device 10. In addition, the +z axis direction is upward, and the −z axis direction is downward.

Heat radiator 11 has, for example, a quadrangular prism shape. Heat radiator 11 is configured by stacking a plurality of plate-shaped heat radiating plates, as described below (see, for example, heat radiator 11 and heat radiating plates 11a to 11f in FIG. 4).

Heat radiator 11 is disposed at the upper surface of a heating element that generates heat (see, for example, heat radiator 11 and heating element 21 in FIG. 2). Heat radiator 11 dissipates heat generated from the heating element. Heat radiator 11 and the heating element may be in contact with each other, or, for example, grease or the like may be applied between heat radiator 11 and the heating element so that the heat of the heating element is smoothly transmitted to heat radiator 11. In the following, “contact” may include the case where grease or the like is applied between objects.

Frame 12 is provided on a surface of heat radiator 11, opposite to the surface where the heating element is located. The periphery of frame 12 has substantially the same shape as the periphery of heat radiator 11, and has, for example, a quadrangular prism shape.

Fan 13 is provided inside frame 12. Fan 13 is provided inside frame 12 in such a way that the rotation axis of fan 13 is located at the center of frame 12. A motor rotates fan 13.

FIG. 2 is aside view illustrating an example of heat radiating device 10. In FIG. 2, the same components as in FIG. 1 are designated by the same reference numerals. FIG. 2 shows heating element 21.

As illustrated in FIG. 2, heat radiating device 10 is disposed in such a way that the lower surface of heat radiator 11 is located on/above the upper surface of heating element 21. Heating element 21 is, for example, an electronic component that generates heat, such as a CPU or SOC. The heat of heating element 21 is absorbed and dissipated by heat radiator 11. Frame 12 and fan 13 housed in frame 12 are provided on a surface of heat radiator 11 where the surface is opposite to another surface where heating element 21 is located.

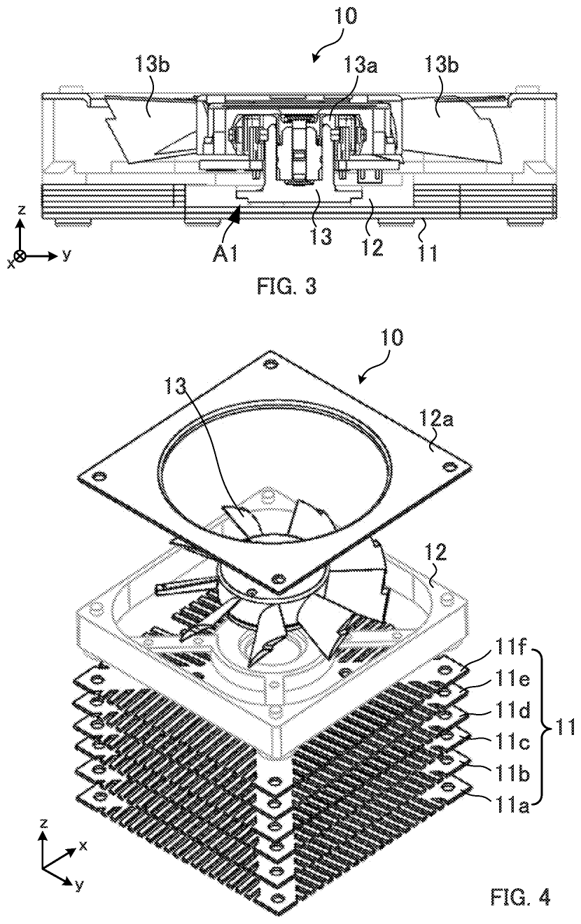

FIG. 3 is a cross-sectional view of heat radiating device 10 taken along arrows A-A of FIG. 1. In FIG. 3, the same components as in FIG. 1 are designated by the same reference numerals. Fan 13 is housed in frame 12.

Fan 13 includes motor 13a and blades (hereinafter also comprehensively referred to as “blade”) 13b. Motor 13a is, for example, a fluid bearing motor.

Blade 13b is connected to the rotation shaft of motor 13a. Blade 13b is located above heat radiator 11. Blade 13b rotates when the rotation shaft of motor 13a rotates. When blade 13b rotates, air above fan 13 is sent into heat radiator 11, thereby cooling heat radiator 11 as well as the heating element.

FIG. 4 is an exploded perspective view illustrating an example of heat radiating device 10. In FIG. 4, the same components as in FIG. 1 are designated by the same reference numerals.

As illustrated in FIG. 4, frame 12 includes cover 12a. Cover 12a includes, for example, a circular opening for taking in air that cools heat radiator 11 and the heating element. The diameter of the opening of cover 12a may be, for example, the same as the diameter of fan 13 (herein, “same” includes “substantially the same”), or may be larger than the diameter of fan 13.

Heat radiator 11 includes heat radiating plates 11a to 11f. Heat radiating plates 11a to 11f are stacked. Grease or the like, for example, may be applied between heat radiating plates 11a to 11f to be stacked for smoothly transmitting heat.

Heat radiating plates 11a to 11f are quadrangular plate-shaped members. The material of heat radiating plates 11a to 11f has high thermal conductivity, and is, for example, aluminum or copper. For example, heat radiating plates 11a to 11f may be formed by Japanese Industrial Standards A1050 or C1020.

Further, heat radiating plates 11a to 11f may be made of not only one material but also different materials combined and stacked. For example, the materials employed as heat radiating plates 11a to 11f may be alternated. Specifically, heat radiating plate 11a may be aluminum, heat radiating plate 11b may be copper, heat radiating plate 11c may be aluminum, heat radiating plate 11d may be copper, heat radiating plate 11e may be aluminum, and heat radiating plate 11f may be copper.

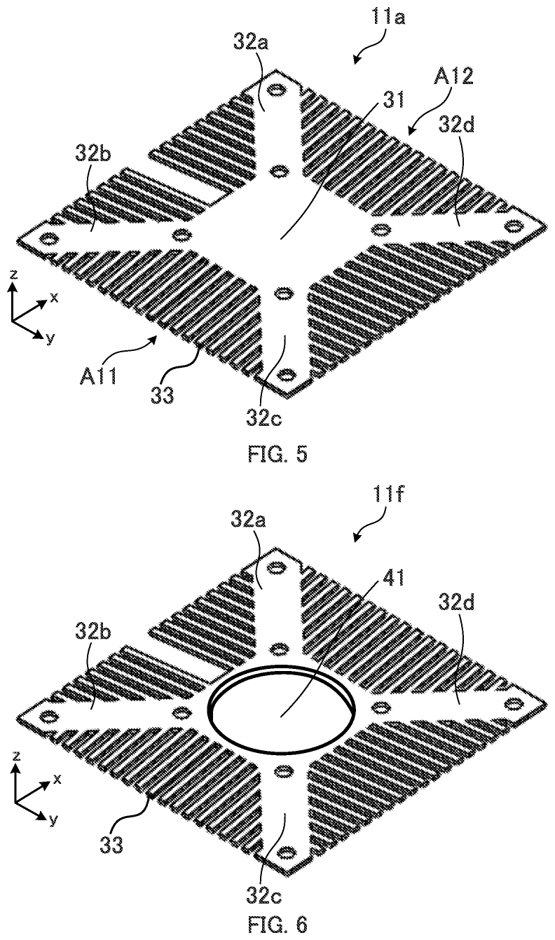

FIG. 5 is a perspective view illustrating an example of heat radiating plate 11a. As illustrated in FIG. 5, heat radiating plate 11a includes core plate section 31, extension plate sections 32a to 32d, and fin 33.

The core plate section 31 is a flat region and has a quadrangular shape. The heating element is disposed at core plate section 31. In other words, the heating element comes into contact with core plate section 31. Core plate section 31 may be formed to have a shape and size in accordance with, for example, the shape and size of the heating element.

Extension plate sections 32a to 32d are flat regions and extend outward (radially) in four directions from the four corners of quadrangular core plate section 31.

Fin 33 is formed at the periphery of core plate section 31 and at the periphery of extension plate sections 32a to 32d. Fin 33 extends outward from the periphery of core plate section 31 and the periphery of extension plate sections 32a to 32d in the in-plane direction (direction perpendicular to the normal of heat radiating plate 11a).

For example, fin 33 extends linearly from the periphery of core plate section 31 and the periphery of extension plate sections 32a to 32d. Further, fin 33 extends linearly from the periphery of core plate section 31 and the periphery of the extension plate sections 32a to 32d without branching. Forming the fin 33 linearly can reduce the cost.

Fin 33 may be formed by, for example, pressing. Further, fin 33 may be formed by, for example, laser processing. For forming fin 33 by laser processing, a quadrangular flat plate, for example, is prepared and grooves are formed by a laser from one side of the prepared flat plate toward the other side facing the one side, thereby forming fin 33.

For example, grooves are formed by a laser from the side indicated by arrow A11 toward the side indicated by arrow A12 in FIG. 5. The lengths of the grooves are set to be the same near the center of the side and shortened toward the end of the side. This procedure is performed at each side of the quadrangular flat plate. As a result, heat radiating plate 11a including core plate section 31, extension plate sections 32a to 32d, and fin 33 as illustrated in FIG. 5 is formed.

Core plate section 31 receives the heat of the heating element. The heat received is transmitted to extension plate sections 32a to 32d. The heat received by core plate section 31 and the heat transmitted to extension plate sections 32a to 32d are dissipated by fin 33 radially extending from core plate section 31 and extension plate sections 32a to 32d. Fin 33 is then air-cooled by fan 13.

Heat radiating plate 11a are described with reference to FIG. 5, and heat radiating plate 11b also has substantially the same shape and size as heat radiating plate 11a.

FIG. 6 is a perspective view illustrating an example of heat radiating plate 11f. In FIG. 6, the same components as in FIG. 5 are designated by the same reference numerals. Heat radiating plate 11f is different from heat radiating plate 11a illustrated in FIG. 5 in that heat radiating plate 11f includes circular opening section 41 in the central portion (herein, “central portion” includes “substantially central portion”).

Opening section 41 is formed at the center of heat radiating plate 11f. Extension plate sections 32a to 32d extend outward from the peripheral region of opening section 41 in four directions.

Fan 13 and frame 12 are partly housed in opening section 41. For example, opening section 41 partly houses fan 13 and frame 12 as indicated by arrow A1 in FIG. 3.

Fin 33 illustrated in FIG. 6 may be formed by, for example, pressing in the same manner as fin 33 illustrated in FIG. 5. Further, fin 33 may be formed by, for example, laser processing. For forming fin 33 by laser processing, a quadrangular flat plate, for example, is prepared and grooves are formed by a laser from one side of the prepared flat plate toward the other side facing the one side, thereby forming fin 33.

As heat radiating plate 11f is described with reference to FIG. 6, heat radiating plates 11c to 11e also have substantially the same shape and size as heat radiating plate 11f. The height of heat radiating device 10 thus can be reduced by providing openings in heat radiating plates 11c to 11f to partly house frame 12 and fan 13.

Heat radiating plates 11a to if are stacked. Heat radiating plate 11a that comes into contact with the heating element includes a core plate section and at least one extension plate section, and heat radiating plate 11b disposed on heat radiating plate 11a also includes a core plate section and at least one extension plate section. Heat radiating plate 11a and heat radiating plate 11b are stacked in such a way that the core plate section and the extension plate sections of heat radiating plate 11b respectively overlap the core plate section and the extension plate sections of heat radiating plate 11a in a plan view (viewed from the +z axis direction) (herein, “overlap” includes “substantially flush with each other”).

Heat radiating plates 11c to 11f disposed on heat radiating plate 11b each include an opening section and at least one extension plate section. Heat radiating plate 11b and heat radiating plate 11c are stacked in such a way that the opening section of heat radiating plate 11c overlaps the core plate section of heat radiating plate 11b, and the extension plate section of heat radiating plate 11c overlaps the extension plate section of heat radiating plate 11b. Heat radiating plates 11c to 11f are stacked in such away that the opening sections of the plates overlap each other, and the extension plate sections of the plates overlap each other. That is, the extension plate sections of heat radiating plates 11c to 11f each including the opening section are formed at positions so as to overlap the extension plate sections of heat radiating plates 11a and 11b each including the core plate section in a plan view.

The heat received by heat radiating plate 11a from the heating element is thus transmitted to heat radiating plate 11b via the core plate section and the extension plate section. The heat transmitted to heat radiating plate 11b is transmitted to the respective extension plate sections of heat radiating plates 11c to 11f via the extension plate section of heat radiating plate 11b. The heat transmitted to heat radiating plates 11a to 11f is dissipated by fins provided in respective heat radiating plates 11a to 11f. Fins of heat radiating plates 11a to 11f are air-cooled by fan 13.

Heat radiating plates 11a to 11f are stacked in such a way that the fins thereof also overlap each other in a plan view. The heat received by heat radiating plate 11a from the heating element is thus also transmitted to heat radiating plates 11b to 11f via the fins.

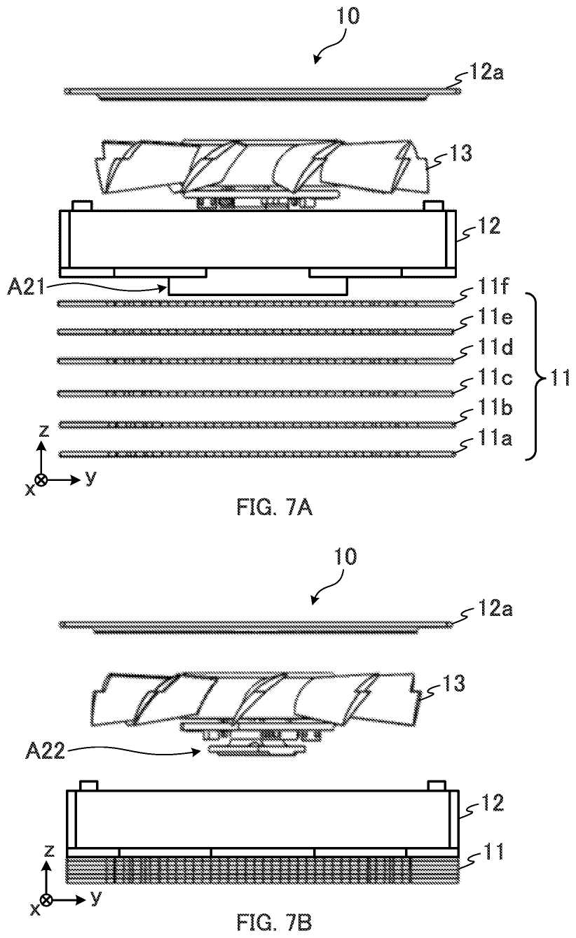

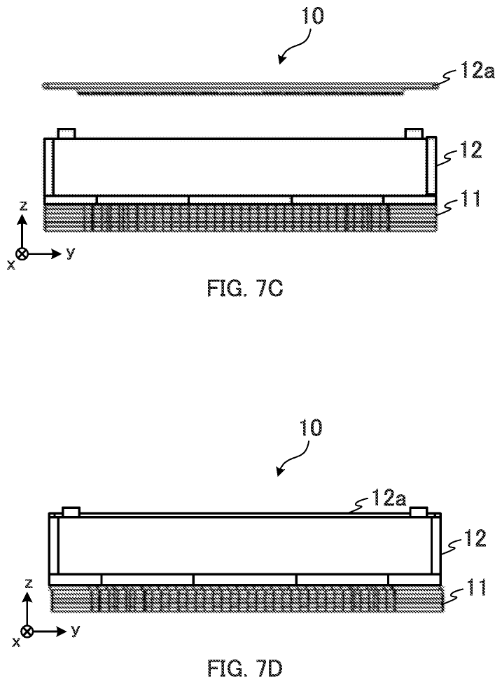

FIGS. 7A to 7D are diagrams for explaining an example of a method for manufacturing heat radiating device 10. In FIGS. 7A to 7D, the same components as in FIG. 4 are designated by the same reference numerals.

FIG. 7A illustrates cover 12a, fan 13, frame 12, and heat radiating plates 11a to 11f of heat radiating device 10 in a separated state. From the state illustrated in FIG. 7A, heat radiating plates 11a to 11f are stacked, and then stacked heat radiating plates 11a to 11f (heat radiator 11) are fixed to frame 12 as illustrated in FIG. 7B.

The central portion of the bottom of frame 12 includes a depression for housing the bottom of fan 13, as indicated by arrow A21 in FIG. 7A. The central portion of the bottom of frame 12 is housed (see, for example, arrow A1 in FIG. 3) in opening sections (see, for example, opening section 41 in FIG. 6) provided in heat radiating plates 11c to 11f.

Heat radiator 11 (heat radiating plates 11a to 11f) may be fixed to frame 12 by, for example, at least one screw. For example, the tip of the screw may be passed through a hole (not shown) provided in heat radiator 11 and inserted into the screw hole provided in frame 12, thereby fixing heat radiator 11 to frame 12.

Further, heat radiating plates 11a to 11f may be fixed with each other (integrated) by, for example, caulking. Heat radiating plates 11a to 11f fixed by caulking may be then fixed to frame 12 with at least one screw.

For example, grease or the like may be applied between heat radiating plates 11a to 11f to be stacked in order to improve heat conduction.

After heat radiator 11 and frame 12 are integrated, fan 13 is housed in and fixed to frame 12 as illustrated in FIG. 7C. The bottom of fan 13 (the part indicated by arrow A22 in FIG. 7B) is housed in a depressed portion in the central portion of the bottom of frame 12 (see, for example, arrow A1 in FIG. 3). In other words, the bottom of fan 13 is housed in the opening sections of heat radiating plates 11c to 11f together with the central portion of the bottom of frame 12.

After fan 13 is fixed to frame 12, cover 12a is fixed to frame 12 as illustrated in FIG. 7D. For example, cover 12a is fixed to frame 12 by at least one screw.

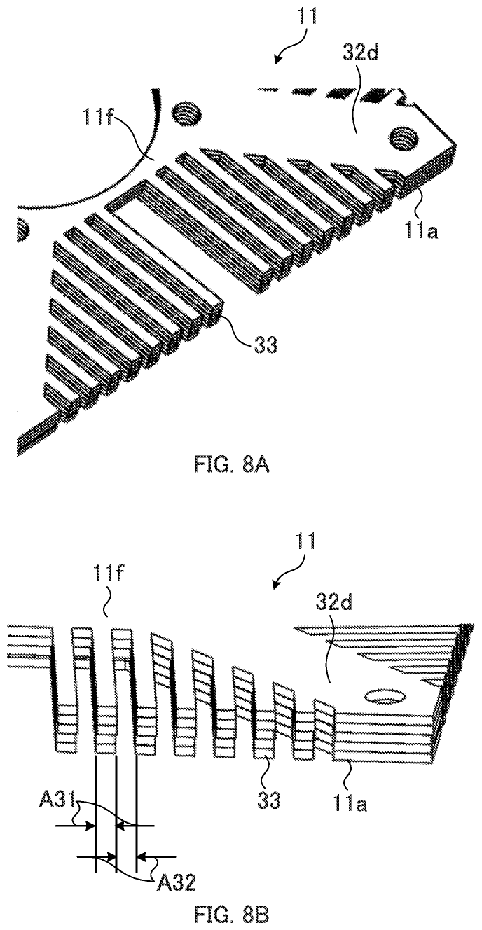

FIGS. 8A and 8B are perspective views illustrating apart of heat radiator 11. In FIGS. 8A and 8B, the same components as in FIGS. 4 to 6 are designated by the same reference numerals.

As described above, the extension plate sections and the fins of heat radiating plates 11a to 11f are respectively formed in the same shape and at the same position. That is, the fins of heat radiating plates 11a to 11b are formed so as to be aligned in the vertical direction (overlapping direction). Therefore, when heat radiating plates 11a to 11f are stacked, as illustrated in FIGS. 8A and 8B, the extension plates and the fins of heat radiating plates 11a to 11f are disposed vertically at the same positions, respectively.

The positions of the fin of the heat radiating plates 11a to 11f were changed, and the amount of heat radiated from heat radiating device 10 was examined. The amount of heat radiated from heat radiating device 10 was examined by, for example, slightly shifting the vertically adjacent fins in the horizontal direction. As a result, a suitable heat radiation amount was obtained when the positions of the fins of respective heat radiating plates 11a to 11f were disposed vertically at the same position (that is, the states illustrated in FIGS. 8A and 8B).

Arrow A31 in FIG. 8B indicates the width of fin 33. Arrow A32 in FIG. 8B indicates the pitch between the fins of fin 33. The ratio of the width of fin 33 to the pitch of fin 33 is “1:1.”

The ratio of the width of fin 33 to the pitch of fin 33 was changed, and then the amount of heat radiated from heat radiating device 10 was examined. As a result, a suitable heat radiation amount was obtained when the ratio of the width of fin 33 to the pitch of fin 33 was “1:1.”

Assuming that heat radiating device 10 is employed to, for example, an electronic device mounted on an automobile, the outer size (length×width) of the heat radiating plate is set to “45 mm×45 mm.” In addition, the thickness (thickness of the heat radiator) when the heat radiating plates are stacked is set to “3 mm.” The ratio of the width of the fin to the pitch of the fin is set to “1:1.” The rotation speed of the fan is set to “3,000 r/min or more and 4,000 r/min or less.”

The number and thickness of the heat radiating plates and the width of the fin were changed under this condition, and the thermal resistance of heat radiating device 10 was measured. When the number of the heat radiating plates was “6,” the thickness of each heat radiating plate was “0.5 mm,” and the width of each fin was “1.0 mm,” a thermal resistance of “2.6 K/W” was obtained.

The number of heat radiating plates to be stacked may be “two or more and 16 or less.” The thickness of the heat radiating plate may be “2.0 mm or less.” The width of the fin may be “0.5 mm or more and 2.5 mm or less.” The rotation speed of the fan may be “1500 r/min or more and 8,000 r/min or less” or “1,500 r/min or more.” In these cases, the target thermal resistance of “2.7 K/W” or less was also obtained.

As described above, heat radiating device 10 includes heat radiator 11 that dissipates heat from heating element 21, and fan 13 provided on a surface, which is opposite to a surface where heating element 21 is located, of radiator 11. Heat radiator 11 is formed by stacking a plurality of plate-shaped heat radiating plates 11a to 11f, and comb-shaped fin 33 extending radially in the in-plane direction is formed at a periphery of each of heat radiating plates 11a to 11f. This configuration allows heat radiating device 10 to have a small size and achieve high cooling performance. Further, heat radiating device 10 does not need to increase the rotation speed of fan 13 due to the high cooling capacity of heat radiator 11, and thus can reduce noise.

In addition, heat radiating plates 11a and 11b of heat radiating plates 11a to 11f each include core plate section 31 that receives heat of heating element 21, and extension plate sections 32a to 32d that extend radially from core plate section 31. Each fin 33 of heat radiating plates 11a and 11b extends radially from core plate section 31 and extension plate sections 32a to 32d. This configuration allows heat radiating device 10 to have a small size and achieve high cooling performance. Further, heat radiating device 10 does not need to increase the rotation speed of fan 13 due to the high cooling capacity of heat radiator 11, and thus can reduce noise.

Heat radiating plates 11c to 11f of heat radiating plates 11a to 11f are each provided with opening section 41, which houses fan 13, formed in the central portion of the heat radiating plate, and includes extension plate sections 32a to 32d that extend radially from the peripheral region of opening section 41. Each fin 33 of heat radiating plates 11c to 11f extends radially from the peripheral region of opening section 41 and extension plate sections 32a to 32d. This configuration allows heat radiating device 10 to have a small size and achieve high cooling performance. Further, heat radiating device 10 does not need to increase the rotation speed of fan 13 due to the high cooling capacity of heat radiator 11, and thus can reduce noise.

Further, extension plate sections 32a to 32d of heat radiating plates 11c to 11f are formed at positions so as to overlap respective extension plate sections 32a to 32d of heat radiating plates 11a and 11b in a plan view. This configuration allows heat radiating device 10 to have a small size and achieve high cooling performance. Further, heat radiating device 10 does not need to increase the rotation speed of fan 13 due to the high cooling capacity of heat radiator 11, and thus can reduce noise.

The width of fin 33 and the pitch of fin 33 are substantially the same. This configuration allows heat radiating device 10 to have a small size and achieve high cooling performance. Further, heat radiating device 10 does not need to increase the rotation speed of fan 13 due to the high cooling capacity of heat radiator 11, and thus can reduce noise.

The pitch of fin 33 is smaller than the thickness of heat radiator 11 (thickness of stacked heat radiating plates 11a to 11f). This configuration allows heat radiating device 10 to have a small size and achieve high cooling performance. Further, heat radiating device 10 does not need to increase the rotation speed of fan 13 due to the high cooling capacity of heat radiator 11, and thus can reduce noise. Stacking heat radiating plates 11a to 11f can easily make the pitch of fin 33 smaller than the thickness of heat radiator 11.

In the above description, heat radiating plates 11a and 11b includes core plate sections and heat radiating plates 11c to 11f includes opening sections, but the present invention is not limited to this configuration. For example, if fan 13 does not have a protruding portion (for example, a portion indicated by arrow A22 in FIG. 7B) at the bottom, heat radiating plates 11c to 11f may include a core plate section in place of an opening section.

In the above, fan 13 takes in air above fan 13 and sends the air into heat radiator 11, but the present invention is not limited to this configuration. For example, fan 13 may take in the air on the heating element 21 side and send the air out above frame 12.

Further, the shapes of the peripheries of heat radiator 11 (heat radiating plates 11a to 11f) and frame 12 are not limited to the shapes shown in the drawings. The shapes may be circular or polygonal, for example. The shapes of the opening sections formed in heat radiating plates 11c to 11f are not limited to the shapes shown in the drawings, either. The shapes may be polygonal, for example. In addition, the shape of the opening of cover 12a is not limited to the shape shown in the drawings. The shape may be polygonal, for example.

The thickness of the heat radiating plate may be “1.0 mm or more and 2.0 mm or less.”

### Second Embodiment

In the second embodiment, a method for fixing the heat radiating plates will be described. In the first embodiment, examples with six heat radiating plates 11a to 11f have been described, but in the second embodiment, three heat radiating plates will be described for making the description simple.

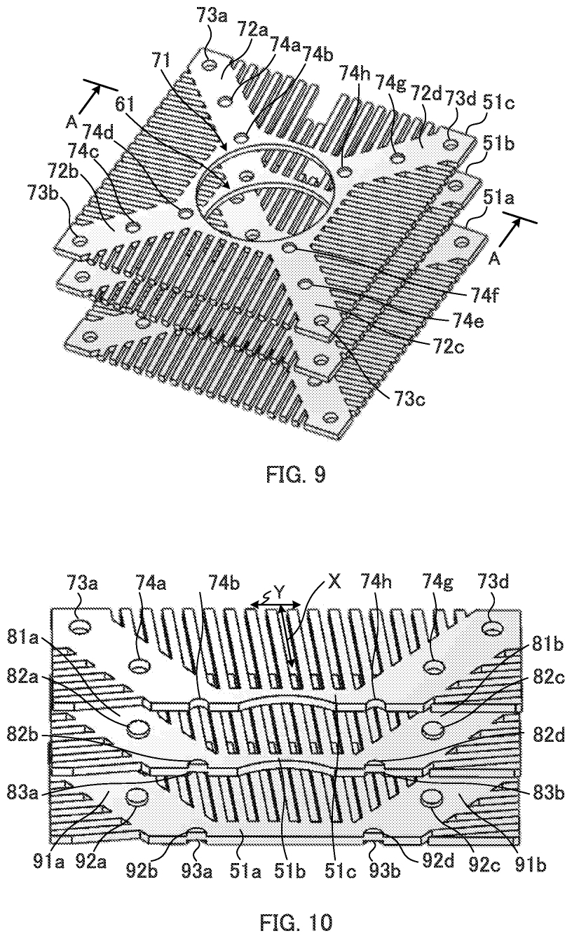

FIG. 9 is a diagram for explaining an example of a method for fixing the heat radiating plate according to the second embodiment. FIG. 9 illustrates three quadrangular heat radiating plates 51a to 51c. In the following, the surface of heat radiating plate 51a facing heat radiating plate 51b is referred to as the front surface of heat radiating plate 51a. The surface opposite to the front surface of heat radiating plate 51a is referred to as the rear surface of heat radiating plate 51a. The surface of heat radiating plate 51b facing heat radiating plate 51a is referred to as the rear surface of heat radiating plate 51b. The surface of heat radiating plate 51b facing heat radiating plate 51c is referred to as the front surface of heat radiating plate 51b. The surface of heat radiating plate 51c facing heat radiating plate 51b is referred to as the rear surface of heat radiating plate 51c. The surface opposite to the rear surface of heat radiating plate 51c is referred to as the front surface of heat radiating plate 51c.

A core plate section that receives heat from a heating element is formed in the central portion of heat radiating plate 51a (see, for example, core plate section 31 in FIG. 5). The core plate section includes a gravity center of heat radiating plate 51a. A comb-shaped fin extending radially toward the periphery of the heat radiating plate is formed around the core plate section. In FIG. 9, the core plate section of heat radiating plate 51a is hidden by heat radiating plates 51b and 51c and thus is not shown.

Circular opening section 61 for partly housing fan 13 and frame 12 is formed in the central portion of heat radiating plate 51b. Opening section 61 includes a gravity center of heat radiating plate 51b. A comb-shaped fin extending radially toward the periphery of the heat radiating plate is formed around opening section 61.

Opening section 71 for partly housing fan 13 and frame 12 is formed in the central portion of heat radiating plate 51c. Opening section 71 includes a gravity center of heat radiating plate 51c. A comb-shaped fin extending radially toward the periphery of the heat radiating plate is formed around opening section 71.

Heat radiating plate 51c includes extension plate sections 72a to 72d extending radially in the in-plane direction. Four extension plate sections 72a to 72d extend radially from the periphery of opening section 71 toward the four corners of heat radiating plate 51c. Heat radiating plate 51b also includes extension plate sections extending from the periphery of opening section 61 toward the four corners of heat radiating plate 51b in the same manner as heat radiating plate 51c. Heat radiating plate 51a includes extension plate sections extending from the core plate section toward the four corners of heat radiating plate 51a. A comb-shaped fin extending radially toward the periphery of the heat radiating plate is formed around the extension plate sections.

Holes 73a to 73d are respectively formed at the ends of extension plate sections 72a to 72d of heat radiating plate 51c. Holes are also respectively formed at the ends of extension plate sections of heat radiating plates 51a and 51b in the same manner as extension plate sections 72a to 72d of heat radiating plate 51c. For example, a screw is inserted into a hole formed at the end of each extension plate section of heat radiating plates 51a to 51c for fixing frame 12 (see, for example, FIGS. 1 and 2).

Holes 74a and 74b are formed in extension plate section 72a of heat radiating plate 51c. Holes 74c and 74d are formed in extension plate section 72b of heat radiating plate 51c. Holes 74e and 74f are formed in extension plate section 72c of heat radiating plate 51c. Holes 74g and 74h are formed in extension plate section 72d of heat radiating plate 51c.

Protrusions (described below) formed on the front surface of heat radiating plate 51b fit into holes 74a to 74h provided in extension plate sections 72a to 72d of heat radiating plate 51c. Heat radiating plate 51b is fixed to heat radiating plate 51c by fitting the protrusions formed on the front surface of heat radiating plate 51b into holes 74a to 74h formed in the heat radiating plate 51c.

In the rear surface of heat radiating plate 51b, formed are depressions (described below) having shapes such that protrusions formed on the front surface of heat radiating plate 51a fit into the depressions. Heat radiating plate 51a is fixed to heat radiating plate 51b by fitting the protrusions formed on the front surface of heat radiating plate 51a into the depressions formed in the rear surface of heat radiating plate 51b.

Heat radiating plates 11a and 11b described with reference to FIG. 4 may be configured by heat radiating plate 51a. Heat radiating plates 11c and 11e described with reference to FIG. 4 may be configured by heat radiating plate 51b. Heat radiating plate 11f described with reference to FIG. 4 may be configured by heat radiating plate 51c.

FIG. 10 is a perspective view illustrating a cross-section taken along arrows A-A of FIG. 9. In FIG. 10, the same components as in FIG. 9 are designated by the same reference numerals.

As illustrated in FIG. 10, heat radiating plate 51b includes extension plate sections 81a and 81b. Columnar protrusions 82a and 82b are formed on the front surface of extension plate section 81a. Columnar depression 83a is formed at a position corresponding to protrusion 82b, in the rear surface of extension plate section 81a. A columnar depression is also formed at a position corresponding to protrusion 82a, on the rear surface of extension plate section 81a, although the depression is not shown in FIG. 10. The protrusions and depressions may be formed by drawing, for example, when the heat radiating plate is formed by pressing. In addition, the protrusions and depressions may be formed by molding, for example, when the heat radiating plate is formed by casting. Further, the protrusions and depressions may be formed by cut-machining when heat radiating plate is formed by cutting.

Columnar protrusions 82c and 82d are formed on the front surface of extension plate section 81b of heat radiating plate 51b. Columnar depression 83b is formed at a position corresponding to protrusion 82d, in the rear surface of extension plate section 81b. A columnar depression is also formed at a position corresponding to protrusion 82c, in the rear surface of extension plate section 81b, although the depression is not shown in FIG. 10.

As illustrated in FIG. 10, heat radiating plate 51a includes extension plate sections 91a and 91b. Columnar protrusions 92a and 92b are formed on the front surface of extension plate section 91a. Columnar depression 93a is formed at a position corresponding to protrusion 92b, in the rear surface of extension plate section 91a. A columnar depression is also formed at a position corresponding to protrusion 92a, in the rear surface of extension plate section 91a, although the depression is not shown in FIG. 10.

Columnar protrusions 92c and 92d are formed on the front surface of extension plate section 91b of heat radiating plate 51a. Columnar depression 93b is formed at a position corresponding to protrusion 92d, in the rear surface of extension plate section 91b. A columnar depression is also formed at a position corresponding to protrusion 92c, in the rear surface of extension plate section 91b, although the depression is not shown in FIG. 10.

Heat radiating plate 51b includes two extension plate sections in addition to extension plate sections 81a and 81b illustrated in FIG. 10 (heat radiating plate 51b includes four extension plate sections in the same manner as extension plate sections 72a to 72d of heat radiating plate 51c illustrated in FIG. 9). Each of not-shown two extension plate sections also include two columnar protrusions formed on the front surface and two columnar depressions formed in the rear surface.

Heat radiating plate 51a includes two extension plate sections in addition to extension plate sections 91a and 91b illustrated in FIG. 10 (heat radiating plate 51a includes four extension plate sections in the same manner as extension plate sections 72a to 72d of heat radiating plate 51c illustrated in FIG. 9). Each of not-shown two extension plate sections also include two columnar protrusions formed on the front surface and two columnar depressions formed in the rear surface.

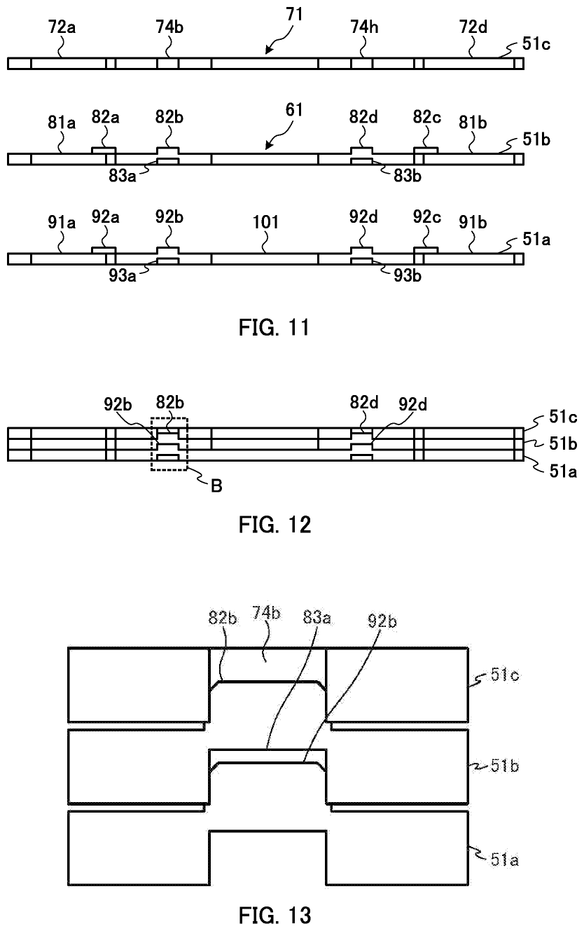

FIG. 11 is a front view of heat radiating plates 51a to 51c of FIG. 10. In FIG. 11, the same components as in FIGS. 9 and 10 are designated by the same reference numerals. As illustrated in FIG. 11, heat radiating plate 51a includes core plate section 101 in the central portion thereof.

Two protrusions 82a and 82b provided on the front surface of extension plate section 81a of heat radiating plate 51b fit into holes 74a and 74b provided in extension plate section 72a of heat radiating plate 51c. Two protrusions 82c and 82d provided on the front surface of extension plate section 81b of heat radiating plate 51b fit into holes 74g and 74h provided in extension plate section 72d of heat radiating plate 51c. Two protrusions (not shown in FIG. 10) provided on each of two extension plate sections of heat radiating plate 51b are also fit into holes 74c, 74d, 74e and 74f provided in the extension plate sections 72b and 72c of extension plate sections 51c.

Protrusion 92b provided on the front surface of extension plate section 91a of heat radiating plate 51a fits into depression 83a provided in the rear surface of extension plate section 81a of heat radiating plate 51b. Protrusion 92a provided on the front surface of extension plate section 91a of heat radiating plate 51a fits into a depression (depression provided at a position corresponding to protrusion 82a) provided in the rear surface of extension plate section 81a of heat radiating plate 51b.

Protrusion 92d provided on the front surface of extension plate section 91b of heat radiating plate 51a fits into depression 83b provided in the rear surface of extension plate section 81b of heat radiating plate 51b. Protrusion 92c provided on the front surface of extension plate section 91b of heat radiating plate 51a fits into a depression (depression provided at a position corresponding to protrusion 82c) provided in the rear surface of extension plate section 81b of heat radiating plate 51b. Two protrusions (not shown in FIG. 10) provided on each of two extension plate sections of heat radiating plate 51a are also fit into depressions provided in the rear surfaces of extension plate sections 81a and 81b of heat radiating plate 51b.

FIG. 12 illustrates stacked heat radiating plates 51a to 51c. In FIG. 12, the same components as in FIG. 11 are designated by the same reference numerals.

Heat radiating plates 51a to 51c are disposed, for example, in such a way that the protrusions provided on the front surface overlap the depressions provided in the rear surface. Pressure is applied to heat radiating plates 51a to 51c from above by, for example, a press machine.

For example, protrusions 82b and 82d provided on the front surface of heat radiating plate 51b illustrated in FIG. 12 enter and fit into holes 74b and 74h of heat radiating plate 51c by the pressure of the press machine. Protrusions 92b and 92d provided on the front surface of heat radiating plate 51a enter and fit into depressions 83a and 83b provided in the rear surface of heat radiating plate 51b by the pressure of the press machine.

FIG. 13 is an enlarged view of a portion shown by the dotted line frame B in FIG. 12. In FIG. 13, the same components as in FIGS. 11 and 12 are designated by the same reference numerals.

The diameter of columnar protrusion 82b formed on the front surface of heat radiating plate 51b is larger than the diameter of hole 74b formed in heat radiating plate 51c. The diameter of columnar protrusion 92b formed on the front surface of heat radiating plate 51a is larger than the diameter of depression 83a formed in the rear surface of heat radiating plate 51b.

Columnar protrusion 82b is inserted and fixed (caulked) into columnar hole 74b having a diameter smaller than that of protrusion 82b by, for example, the pressure of a press machine. The peripheral surface of protrusion 82b thus comes into contact with the peripheral surface of hole 74b with large force. Columnar protrusion 92b is inserted and fixed (caulked) into columnar depression 83a having a diameter smaller than that of protrusion 92b by, for example, the pressure of the press machine. The peripheral surface of protrusion 92b thus comes into contact with the peripheral surface of depression 83a with large force.

The relationship between the diameter of hole 74b and the diameter of protrusion 82b, and the relationship between the diameter of depression 83a and the diameter of protrusion 92b may be determined so as to satisfy the following conditions 1 and 2.

Condition 1: Each gap between heat radiating plates 51a to 51c that are stacked and fixed is, for example, 0.03 mm or less.

Condition 2: The tensile strength of the stacked heat radiating plates 51a to 51c (the force required to peel off the stacked and fixed heat radiating plates 51a to 51c from each other) is, for example, 68.6 N or more.

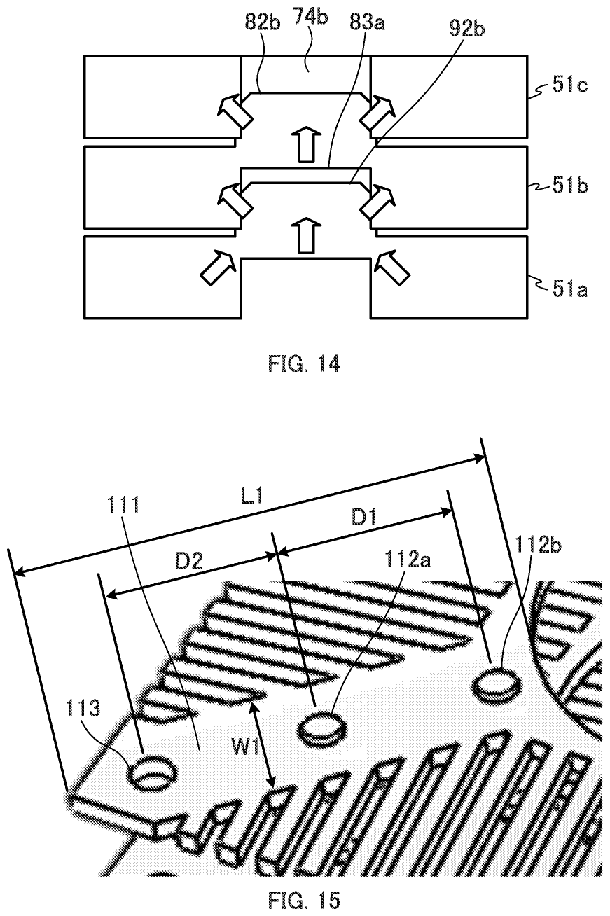

FIG. 14 is a diagram for explaining the heat conduction of heat radiating plates 51a to 51c. In FIG. 14, the same components as in FIG. 13 are designated by the same reference numerals.

The heating element generating heat is disposed at the rear surface of heat radiating plate 51a. In this case, the heat of the heating element is conducted as shown by the arrows in FIG. 14.

The peripheral surface of protrusion 82b and the peripheral surface of hole 74b are in contact with each other with a very strong force (for example, a tensile strength of 68.6 N or more) by caulking. The adhesiveness between the peripheral surface of protrusion 82b and the peripheral surface of hole 74b is thus very high, and the heat conduction of the portion where the peripheral surface of protrusion 82b and the peripheral surface of hole 74b are in contact is very high. This configuration allows for high cooling performance without applying thermal conductive grease or the like, even when a gap of 0.3 mm is generated between heat radiating plate 51b and heat radiating plate 51c, for example.

In addition, the peripheral surface of protrusion 92b and the peripheral surface of depression 83a are in contact with each other with a very strong force (for example, a tensile strength of 68.6 N or more) by caulking. The adhesiveness between the peripheral surface of protrusion 92b and the peripheral surface of depression 83a is thus very high, and the heat conduction of the portion where the peripheral surface of protrusion 92b and the peripheral surface of depression 83a are in contact is very high. This configuration allows for high cooling performance without applying thermal conductive grease or the like, even when a gap of 0.3 mm is generated between heat radiating plate 51a and heat radiating plate 51b, for example.

Stacked heat radiating plates 51a to 51c can achieve high cooling performance without applying heat conductive grease or the like, but naturally, heat conductive grease or the like may be applied between heat radiating plates 51a to 51c.

FIG. 15 is a diagram for explaining an example of the dimensions of heat radiating plate 51b. FIG. 15 illustrates a portion of heat radiating plate 51b. Heat radiating plate 51b includes extension plate section 111. Protrusions 112a and 112b are formed on the front surface of extension plate section 111. In addition, hole 113 is formed in extension plate section 111.

The diameter of protrusions 112a and 112b is, for example, 2 mm. The diameter of the holes (or depressions) that fit with protrusions 112a and 112b is determined so that the tensile strength becomes 68.6 N or more.

Length L1 of extension plate section 111 is, for example, “22±3 mm.” Width W1 of extension plate section 111 is, for example, “6±1 mm.”

Distance D1 between protrusions 112a and 112b is, for example, “8±1 mm.” Distance D2 between hole 113 and protrusion 112a is, for example, “8±1 mm.”

The diameters of protrusions 112a and 112b may be “1 mm or more and 5 mm or less.” Width W1 of extension plate section 111 may be determined so that extension plate section 111 has a width of 1 mm or more on both sides of protrusions 112a and 112b in the width direction. For example, when the diameters of protrusions 112a and 112b are 5 mm, width W1 of extension plate section 111 may be 7 mm or more so that extension plate section 111 has a width of 1 mm or more on both sides of protrusions 112a and 112b in the width direction. By designing width W1 of extension plate section 111 to have a width of 1 mm or more on both sides of protrusions 112a and 112b in the width direction, protrusions 112a and 112b can be easily formed on extension plate section 111.

The number of protrusions formed on extension plate section 111 may be two or more. It is desirable that one of the plurality of protrusions formed on extension plate section 111 is formed at the central portion of extension plate section 111 in the length direction. For example, protrusion 112a in FIG. 15 is formed at the central portion of extension plate section 111 in the length direction. This configuration can improve the heat conduction between heat radiating plates 51a to 51c.

Further, two or more protrusions may be formed on the extension plate section III in the width direction of extension plate section 111.

Distance D1 may be “1 mm or more and 20 mm or less.” By setting distance D1 to 1 mm or more, protrusions 112a and 112b can be easily formed on extension plate section 111. Further, by setting distance D1 to 20 mm or less, the heat conduction between heat radiating plates 51a to 51c can be improved.

The dimensions of extension plate section 111 and protrusions 112a and 112b of heat radiating plate 51b are described with reference to FIG. 15, and the other extension plate sections (the remaining three extension plate sections) of heat radiating plate 51b also have substantially the same dimensions. Heat radiating plates 51a and 51c also have dimensions substantially the same as the dimensions illustrated in FIG. 15.

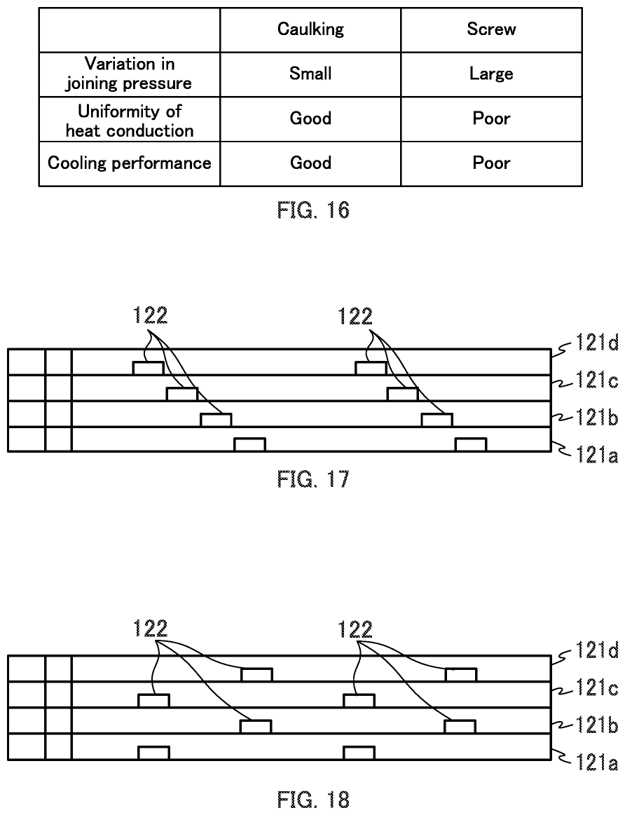

FIG. 16 is a diagram for explaining the difference between the case where heat radiating plates 51a to 51c are fixed by caulking and the case where the heat radiating plates are fixed by screws. The “caulking” shown in FIG. 16 indicates a set of heat radiating plates obtained by stacking and fixing heat radiating plates 51a to 51c described with reference to FIGS. 9 to 15 by caulking. The “screw” shown in FIG. 16 indicates a set of heat radiating plates obtained by making the protrusions and depressions of heat radiating plates 51a to 51c described with reference to FIGS. 9 to 15 into holes (through holes), and stacking and fixing heat radiating plates 51a to 51c by threading screws through the holes.

As shown in FIG. 16, the “caulking” has a smaller variation in joining pressure than the “screw.” For example, in the “screw,” the joining pressure of the heat radiating plates at screw portions differs depending on the variation in the tightening force of the screws. On the other hand, the variation in joining pressure is small in fitting portions of heat radiating plates 51a to 51c in the caulking.

As the “caulking” has a smaller variation in joining pressure than the “screw,” heat is evenly transmitted to each part of heat radiating plates 51a to 51c. As the “screw” has a larger variation in joining pressure than “caulking,” parts with suitable heat conduction (parts with high joining pressure) and parts with poor heat conduction (parts with low joining pressure) are generated, heat is not evenly transmitted through the heat radiating plate.

When the heat is evenly distributed in the heat radiating plate, the heat can be efficiently radiated from the entire fin, thereby improving cooling performance. Therefore, the “caulking” achieves higher cooling performance than the “screw” as shown in FIG. 16.

As described above, the heat radiating device includes a heat radiator which is formed by stacking plate-shaped heat radiating plates 51a to 51c, and which dissipates heat from a heating element. Each of heat radiating plates 51a to 51c of the heat radiator includes: a first region (opening section 61, 71, or core plate section 101) including a gravity center, at least one second region (extension plate section 72a to 72d, 81a, 81b, 91a, 91b, 111) extending radially in the in-plane direction from the first region toward a periphery of the heat radiating plate; and comb-shaped fin which is formed in a third region around the first region and the second region, and extends radially in the in-plane direction toward the periphery. Further, at least one of heat radiating plates 51a to 51c (radiating plates 51a, 51b) of the heat radiator includes: at least one first fitting section (protrusions 82a to 82d, 92a to 92d) formed on the front surface of the heat radiating plate in the second region; and at least one second fitting section (recesses 83a, 83b, 93a, 93b) which is formed on the rear surface of the heat radiating plate in the second region and has a shape so as to fit with the first fitting section. The heat of the heating element is thus transmitted through heat radiating plates 51a to 51c via fitting portions between the first fitting sections and the second fitting sections, and the heat radiating device can achieve a small size and high cooling capacity. Further, the heat radiating device does not need to increase the rotation speed of fan 13 due to the high cooling capacity of the heat radiator, and thus can reduce noise.

Heat radiating plates 51a to 51c are stacked and fixed by fitting the first fitting section and the second fitting section. As a result, the heat radiating device does not require the steps of screw insertion and screw rotation in the manufacturing process, and thus can reduce the cost as compared with, for example, stacking and fixing with screws.

Some of heat radiating plates 51a to 51c, i.e., heat radiating plates 51b and 51c, include opening sections 61 and 71. The heat radiating device thus prevents heat from accumulating in the core plate section, and conducts the heat to the extension plate section, thereby efficiently dissipating the heat from the fin.

In the above description, extension plate sections 72a to 72d of heat radiating plate 51c include holes 74a to 74h, but the present invention is not limited to this configuration. Heat radiating plate 51a may be provided with protrusions on the front surface at positions corresponding to holes 74a to 74h of extension plate sections 72a to 72d, and may be provided with depressions on the rear surface. This configuration enables heat radiating plates 51a to 51c to have the same shape. Heat radiating plates 51a to 51c may have the same shape or different shapes, but the same shape allows to manufacture the heat radiating plates by the same manufacturing process, and thus can reduce the cost. Heat radiating plate 51a may be flat provided with no protrusion on the front surface at positions corresponding to holes 74a to 74h of extension plate sections 72a to 72d.

Further, the distance between the pitches may be smaller than the thickness of each of heat radiating plates 11a to 11f. In this case, the target thermal resistance of “2.7 K/W” or less was also obtained.

The heat radiating plate to be in contact with the heating element may be made of copper having suitable thermal conductivity, and the other heat radiating plates may be made of aluminum, which is cheaper than copper. This configuration allows the heat radiating device to efficiently dissipate the heat, as well as to reduce the cost.

Further, the direction of the pitch (groove) of the fin does not have to be perpendicular to the side of the heat radiating plate. For example, the direction X of the pitch of the fin does not have to be perpendicular to the direction Y of the side of heat radiating plate 51c as illustrated in FIG. 10. This configuration allows for the reduction of the loudness of sound generated when wind of fan 13 hits the fin.

In the above description, protrusions and depressions of heat radiating plates 51a to 51c are formed at the same positions, but the present invention is not limited to this configuration.

FIGS. 17 and 18 are diagrams for explaining the positions of protrusions and depressions formed in the extension plate sections. FIGS. 17 and 18 illustrate cross sections of, for example, extension plate section 111 illustrated in FIG. 15 in the length direction. FIGS. 17 and 18 each illustrate an example of four heat radiating plates 121a to 121d.

As illustrated in FIG. 17, protrusions 122 may be formed in such a way that the respective positions thereof in heat radiating plates 121a to 121d are different from each other. As illustrated in FIG. 18, protrusions 122 may be at the same position in some heat radiating plates (e.g., 121b and 121d).

In the above description, protrusions are formed on the front surface and depressions are formed in the rear surface in the heat radiating plate, but depressions may be formed in the front surface and protrusions may be formed on the rear surface in the heat radiating plate. The shapes of the protrusion and depression are not limited to a circular cylinder shape. The shapes of the protrusions and depressions may be polygonal, oval or the like. The height, size (for example, diameter), and number of protrusions may be changed depending on the amount of heat to be cooled or the size of heat radiating device 10. In addition, the height, size (for example, diameter), and number of depressions may be changed depending on the amount of heat to be cooled or the size of heat radiating device 10.

### Third Embodiment

At least one gap having the same (including substantially the same) size as the pitch of fin 33 (see arrows A32 in FIG. 8B) is formed between heat radiator 11 and frame 12 in the third embodiment. In the third embodiment, the air passage resistance is adjusted by letting out a part of wind generated by fan 13 from the gap formed between heat radiator 11 and frame 12 to increase the air volume of wind flowing to fin 33, thereby achieving a small size and high cooling performance.

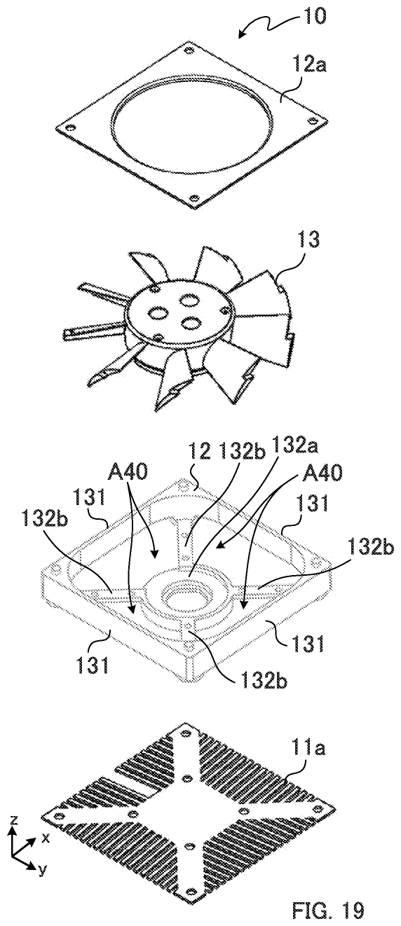

FIG. 19 is an exploded perspective view of heat radiating device 10 according to the third embodiment. In FIG. 19, the same components as in FIG. 4 are designated by the same reference numerals. In FIG. 19, the illustration of heat radiating plates 11b to 11f among heat radiating plates 11a to 11f illustrated in FIG. 4 are omitted, and only heat radiating plate 11a is shown.

Side surface section 131 of frame 12 has a quadrangular shape so as to surround the periphery of fan 13 as illustrated in FIG. 19.

Bottom surface section 132a of frame 12 has a circular shape and is disposed in the central portion of frame 12. Bottom surface section 132a includes a depression and a hole so as to house the bottom of fan 13 (see a portion indicated by arrow A22 in FIG. 7B).

Bottom surface section 132b of frame 12 extends linearly from the periphery of circular bottom surface portion 132a disposed at the central portion of frame 12 toward the four corners of quadrangular side surface section 131 to form a cross shape. Bottom surface section 132b is disposed on and fixed to extension plate sections 32a to 32d of heat radiating plate 11f illustrated in FIG. 6.

Bottom surface sections 132a and 132b form four openings in frame 12 as indicated by arrows A40 in FIG. 19. The wind from fan 13 is sent to heat radiator 11 through the four openings of frame 12.

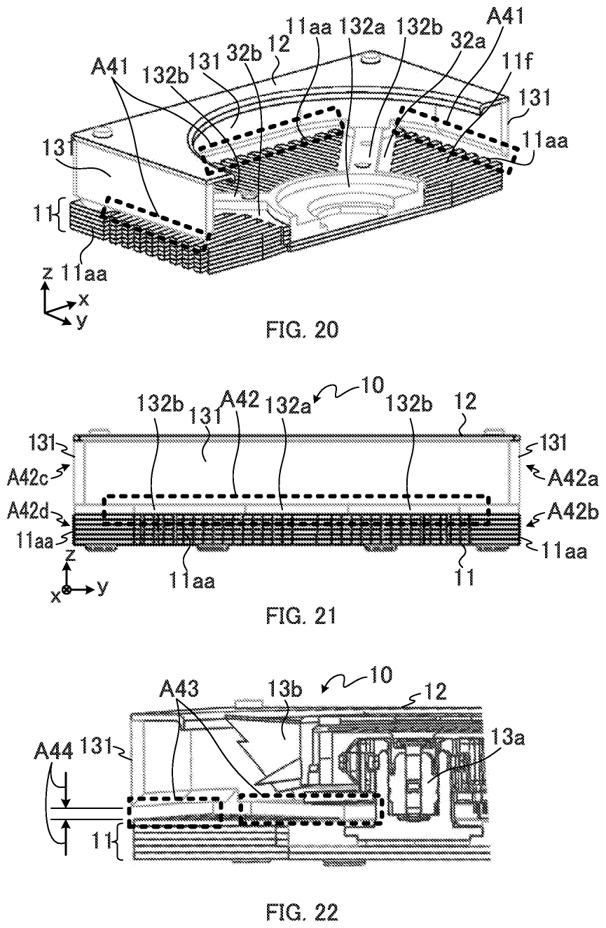

FIG. 20 is a cross-sectional perspective view of heat radiator 11 and frame 12. In FIG. 20, the same components as in FIG. 19 are designated by the same reference numerals.

As illustrated in FIG. 20, frame 12 is fixed to heat radiating plate 11f located at the top of heat radiator 11. Bottom surface section 132b of frame 12 illustrated in FIG. 20 is fixed to extension plate sections 32a and 32b of heat radiating plate 11f.

Side surface section 11aa of heat radiator 11 has the same shape and size as side surface section 131 of frame 12. That is, side surface section 11aa of heat radiator 11 has a quadrangular shape having the same size as side surface section 131 of frame 12. The surface of side surface section 11aa of heat radiator 11 and the surface of side surface section 131 of frame 12 are thus flush with each other.

Frame 12 is fixed to heat radiating plate 11f of heat radiator 11 so that at least one gap is formed between frame 12 and heat radiator 11. In other words, frame 12 is configured in such a way that at least one gap is formed between frame 12 and heat radiator 11 when fixed to heat radiator 11.

The dotted line frames A41 illustrated in FIG. 20 indicate gap portions formed between frame 12 and heat radiator 11. The gaps indicated by dotted line frames A41 are formed between side surface section 131 of frame 12 and side surface section 11aa of heat radiator 11. In other words, the gaps are formed between the peripheral surface of frame 12 and the peripheral surface of heat radiator 11. In yet other words, the gaps are formed between the lower end of frame 12 (the lower end of side surface section 131) and the upper surface of heat radiator 11. In yet other words, the gaps are formed between the end, facing the heat radiator 11, of side surface section 131 of frame 12 and a surface, facing frame 12, of heat radiator 11.

FIG. 21 is a side view of heat radiating device 10. In FIG. 21, the same components as in FIGS. 19 and 20 are designated by the same reference numerals. Dotted line frame A42 illustrated in FIG. 21 indicates a gap formed between side surface section 131 of frame 12 and side surface section 11aa of heat radiator 11.

As described above, the surface of side surface section 131 of frame 12 and the surface of side surface section 11aa of heat radiator 11 are flush with each other. In FIG. 21, for example, the surface of side surface section 131 of frame 12 indicated by arrow A42a and the surface of side surface section 11aa of heat radiator 11 indicated by arrow A42b are flush with each other. In FIG. 21, for example, the surface of side surface section 131 of frame 12 indicated by arrow A42c and the surface of side surface section 11aa of heat radiator 11 indicated by arrow A42d are flush with each other.

FIG. 22 is a partial cross-sectional view of heat radiating device 10. In FIG. 22, the same components as in FIGS. 19 and 20 are designated by the same reference numerals. Dotted line frames A43 illustrated in FIG. 22 indicate gaps formed between side surface section 131 of frame 12 and side surface section 11aa of heat radiator 11.

The gap between side surface section 131 of frame 12 and side surface section 11aa of heat radiator 11 is formed so as to have the same size as the pitch of fin 33 (see arrows A32 in FIG. 8B). For example, arrows A44 in FIG. 22 indicate the size (width) of the gap between side surface section 131 of frame 12 and side surface section 11aa of heat radiator 11. When the pitch of fin 33 is set to 1 mm, for example, the size of the gap indicated by arrows A44 in FIG. 22 becomes 1 mm.

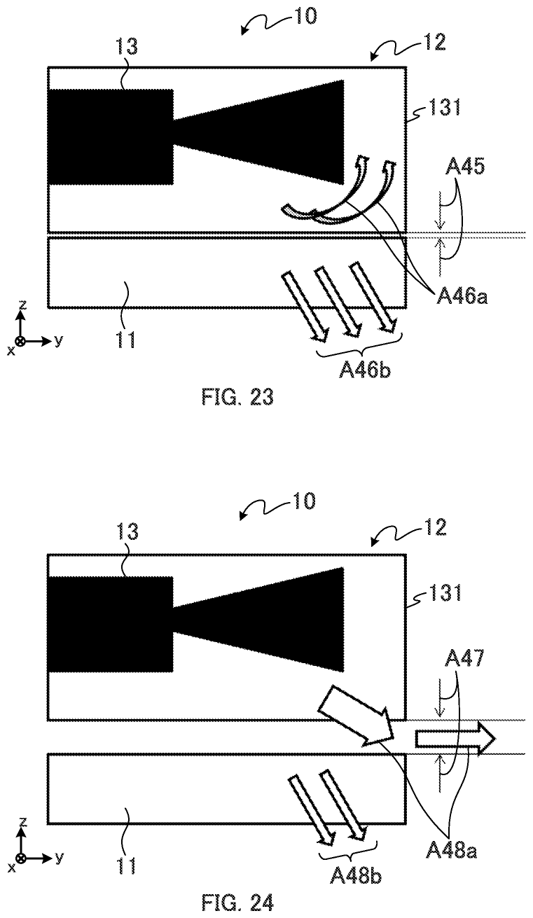

FIGS. 23, 24 and 25 are diagrams for explaining the air volume of heat radiating device 10. FIGS. 23, 24 and 25 illustrate a part of a cross section of heat radiating device 10. In FIGS. 23, 24 and 25, the same components as in FIGS. 3 and 21 are designated by the same reference numerals. Heat radiating device 10 illustrated in FIGS. 23, 24 and 25 has a simplified shape and the like with respect to heat radiating device 10 illustrated in FIGS. 3 and 21.

Fan 13 illustrated in FIGS. 23, 24 and 25 sends out wind in the −z axis direction. That is, fan 13 sends out the wind toward heat radiator 11.

Arrows A45 illustrated in FIG. 23 indicate a gap between frame 12 and heat radiator 11. The gap indicated by arrows A45 in FIG. 23 is narrower than the pitch of fin 33 of heat radiator 11.

When the gap between frame 12 and heat radiator 11 is narrower than the pitch of fin 33 of heat radiator 11, the air passage resistance of wind from fan 13 toward heat radiator 11 increases. As indicated by arrows A46a in FIG. 23, apart of the wind from fan 13 thus flows (returns) to the fan 13 side.

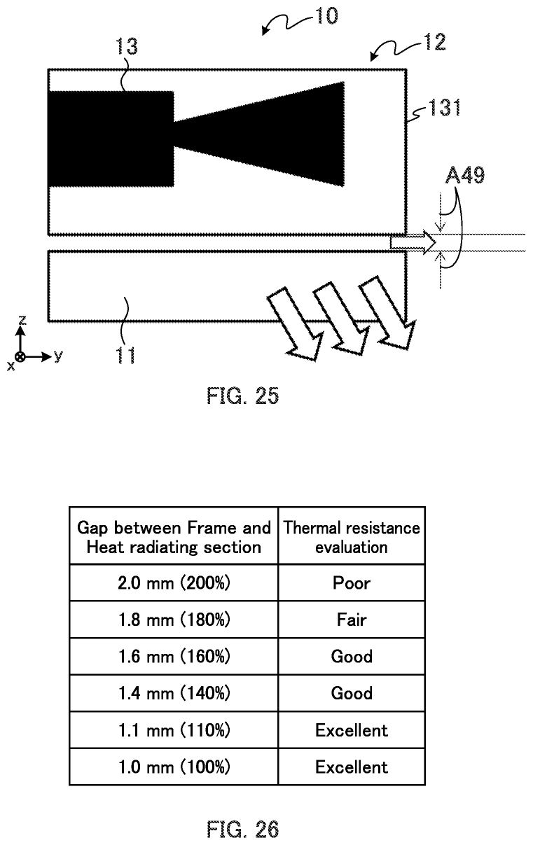

When a part of the wind from fan 13 returns to the fan 13 side, the amount of air flowing through fin 33 of heat radiator 11 decreases as indicated by arrows A46b in FIG. 23. Therefore, when the gap between frame 12 and heat radiator 11 is narrower than the pitch of fin 33 of heat radiator 11, the cooling performance of heat radiating device 10 decreases as compared with heat radiating device 10 in FIG. 25 described below.

Arrows A47 illustrated in FIG. 24 indicate a gap between frame 12 and heat radiator 11. The gap indicated by arrows A47 in FIG. 24 is wider than the pitch of fin 33 of heat radiator 11.

When the gap between frame 12 and heat radiator 11 is wider than the pitch of fin 33 of heat radiator 11, a part of wind from fan 13 toward heat radiator 11 is discharged to the outside of frame 12 as indicated by arrows A48a in FIG. 24. The larger the gap between frame 12 and heat radiator 11 is, the larger the amount of air discharged to the outside of frame 12 becomes.

When the amount of air discharged to the outside of frame 12 is large, the amount of air flowing through fin 33 of heat radiator 11 decreases as indicated by arrows A48b in FIG. 24. Therefore, when the gap between frame 12 and heat radiator 11 is wider than the pitch of fin 33 of heat radiator 11, the cooling performance of heat radiating device 10 decreases as compared with heat radiating device 10 in FIG. 25 described in the following.

Arrows A49 illustrated in FIG. 25 indicate a gap between frame 12 and heat radiator 11. The gap indicated by arrows A49 in FIG. 25 is the same as the pitch of fin 33 of heat radiator 11.

When the gap between frame 12 and heat radiator 11 is the same as the pitch of fin 33 of heat radiator 11, the air passage resistance of wind from fan 13 toward heat radiator 11 becomes smaller than the air passage resistance described with reference to FIG. 23. In addition, the amount of air discharged to the outside of frame 12 becomes smaller than the amount of air described with reference to FIG. 24.

That is, when the gap between frame 12 and heat radiator 11 is the same as the pitch of fin 33 of heat radiator 11, the amount of air flowing through fin 33 of heat radiator 11 becomes large as compared to FIGS. 23 and 24. Therefore, when the gap between frame 12 and heat radiator 11 is the same as the pitch of fin 33 of heat radiator 11, heat radiating device 10 achieves high heat dissipation performance.

FIG. 26 shows the thermal resistance evaluation of heat radiating device 10. The thermal resistance evaluation in FIG. 26 was performed under the following conditions.

Number of heat radiating plates in heat radiator 11: 6

Outer sizes (length×width) of frame 12 and heat radiator 11: 45 mm×45 mm

Thickness of each heat radiating plate in heat radiator 11: 0.5 mm

Width and pitch of fin 33 in heat radiator 11: 1.0 mm

Rotation speed of fan 13: 3,600 r/min

FIG. 26 shows the thermal resistance evaluation when the gap between frame 12 and heat radiator 11 is the same as the pitch “1.0 mm” of fin 33 of heat radiator 11. FIG. 26 also shows the thermal resistance evaluation when the gap (1.1 mm or more and 2.0 mm or less) between frame 12 and heat radiator 11 is larger than the pitch “1.0 mm” of fin 33 of heat radiator 11.

As shown in FIG. 26, as the gap between frame 12 and heat radiator 11 approaches the pitch “1.0 mm” of fin 33 of heat radiator 11, the thermal resistance evaluation improved (the thermal resistance value decreased).

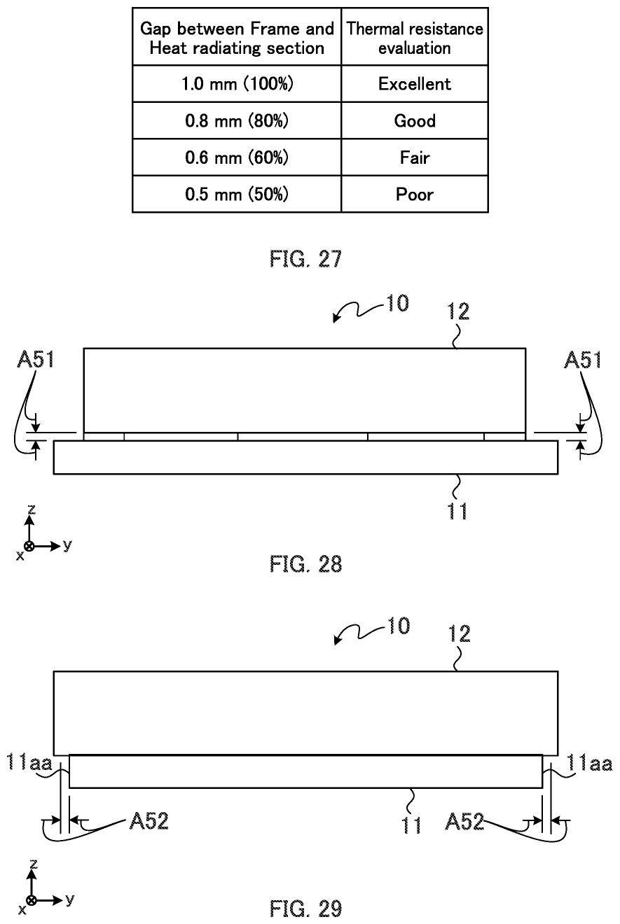

FIG. 27 shows the thermal resistance evaluation of heat radiating device 10. The thermal resistance evaluation in FIG. 27 was performed under the same conditions as in FIG. 26.

FIG. 27 shows the thermal resistance evaluation when the gap between frame 12 and heat radiator 11 is the same as the pitch “1.0 mm” of fin 33 of heat radiator 11. FIG. 27 also shows the thermal resistance evaluation when the gap (0.5 mm or more and 0.8 mm or less) between frame 12 and heat radiator 11 is smaller than the pitch “1.0 mm” of fin 33 of heat radiator 11.

As shown in FIG. 27, as the gap between frame 12 and heat radiator 11 approaches the pitch “1.0 mm” of fin 33 of heat radiator 11, the thermal resistance evaluation improved (the thermal resistance value decreased).

As seem from the thermal resistance evaluations in FIGS. 26 and 27, heat radiating device 10 achieves the highest thermalresistance evaluation when the gap between frame 12 and heat radiator 11 is the same as the pitch “1.0 mm” of fin 33 of heat radiator 11. Heat radiating device 10 thus achieves the highest cooling performance when the gap between frame 12 and heat radiator 11 is the same as the pitch of fin 33 of heat radiator 11. Further, heat radiating device 10 achieves high cooling performance when the gap between frame 12 and heat radiator 11 is close to the pitch of fin 33 of heat radiator 11.

As described above, heat radiating device 10 is provided with heat radiator 11 which is formed by stacking a plurality of plate-shaped heat radiating plates 11a to 11f and which dissipates heat from a heating element; and frame 12 which houses fan 13 and which is provided on a surface of radiator 11, the surface being opposite to another surface where a heating element is located. Comb-shaped fin 33 extending radially in the in-plane direction is formed at a periphery of each of heat radiating plates 11a to 11f of heat radiating device 10, and gaps having the same size as the pitch of fin 33 (see, for example, arrows A32 in FIG. 8B) are formed between frame 12 and heat radiator 11 (see, for example, the dotted line frames A41 in FIG. 20). This configuration allows a part of the wind from fan 13 to be appropriately discharged from the gaps between frame 12 and heat radiator 11, thereby reducing the air passage resistance of the wind from fan 13 to heat radiator 11. A large amount of wind from fan 13 thus flows through fin 33 of heat radiator 11, and heat radiating device 10 can achieve a small size and high cooling capacity. Further, the heat radiating device does not need to increase the rotation speed of the fan due to the high cooling capacity of the heat radiator, and thus can reduce noise.

(Modification 1)

In the above description, heat radiator 11 and frame 12 have the same size, but the present invention is not limited to this configuration. Heat radiator 11 may be formed larger than frame 12.

FIG. 28 is a side view of heat radiating device 10. In FIG. 28, the same components as in FIG. 21 are designated by the same reference numerals. Heat radiating device 10 illustrated in FIG. 28 has a simplified shape and the like with respect to heat radiating device 10 illustrated in FIG. 21.

As illustrated in FIG. 28, heat radiator 11 may be formed larger than frame 12. More specifically, the outer edge of frame 12 may have a size so as to fit in the outer edge of heat radiator 11 in the plan view of heat radiating device 10.

In this case, at least one gap having the same size as the pitch of fin 33 is also formed between frame 12 and heat radiator 11 as indicated by arrows A51 in FIG. 28. This configuration also allows heat radiating device 10 to have a small size and achieve high cooling performance.

(Modification 2)

In the above description, heat radiator 11 and frame 12 have the same size, but the present invention is not limited to this configuration. Heat radiator 11 may be formed smaller than frame 12.

FIG. 29 is a side view of heat radiating device 10. In FIG. 29, the same components as in FIG. 21 are designated by the same reference numerals. Heat radiating device 10 illustrated in FIG. 29 has a simplified shape and the like with respect to heat radiating device 10 illustrated in FIG. 21.

As illustrated in FIG. 29, heat radiator 11 may be formed smaller than frame 12. More specifically, the outer edge of frame 12 may have a size so as to house the outer edge of heat radiator 11 in the plan view of heat radiating device 10.

In this case, the lower end of frame 12 and the upper surface of heat radiator 11 may be flush with each other. As indicated by arrows A52 in FIG. 29, at least one gap having the same size as the pitch of fin 33 is also formed between the inner peripheral surface of frame 12 and side surface section 11aa of heat radiator 11. This configuration also allows heat radiating device 10 to have a small size and achieve high cooling performance.

The disclosures of Japanese Patent Applications No. 2018-111089 filed on Jun. 11, 2018, No. 2018-236218 filed on Dec. 18, 2018, and Japanese Patent Applications No. 2019-031813 filed on Feb. 25, 2019, the disclosure of which including the specifications, drawings and abstracts are incorporated herein by reference in their entirety.

### INDUSTRIAL APPLICABILITY

The present disclosure is particularly advantageous as a heat radiating device for, for example, a heating element of an electronic device, such as a CPU or SOC, mounted on an automobile.

### REFERENCE SIGNS LIST

10 Heat radiating device
11 Heat radiator
11a to 11f, 51a to 51c, 121a to 121d Heat radiating plate
12 Frame
12a Cover
13 Fan
13a Motor
13b Blade
21 Heating element
31, 101 Core plate section
32a to 32d, 72a to 72d, 81a, 81b, 91a, 91b, 111 Extension plate section
33 Fin
41, 61, 71 Opening section
73a to 73d, 74a to 74h, 113 Hole
82a to 82d, 92a to 92d, 112a, 112b, 122 Protrusion
83a, 83b, 93a, 93b depression
131, 11aa Side surface section
132a, 132b Bottom surface section

1. A heat radiating device, comprising:
a heat radiator that dissipates heat of a heating element; and
a fan provided on a surface of the heat radiator, the surface being opposite to another surface where the heating element is located,
wherein
the heat radiator is formed by stacking a plurality of heat radiating plates each having a plate shape,
a fin extending radially in an in-plane direction is formed at a periphery of each of the plurality of the heat radiating plates, the fin having a comb shape,
a thickness of the heat radiating plate is 2 mm or less,
a first heat radiating plate of the plurality of heat radiating plates includes
a heat receiving region receiving the heat of the heating element, and
a first extension region extending radially from the heat receiving region,
the fin of the first heat radiating plate extends radially from the heat receiving region and the first extension region,
a pitch of the fin is 0.5 mm or more and 2.5 mm or less,
a second heat radiating plate of the plurality of heat radiating plates includes a central portion in which an opening for housing the fan is formed, and a second extension region extending radially from a peripheral region of the opening,
the fin of the second heat radiating plate extends radially from the peripheral region of the opening and the second extension region,
the first extension region and the second extension region have identical shapes,
the fin of the first heat radiating plate and the fin of the second heat radiating plate have identical shapes, and
the first heat radiating plate and the second heat radiating plate are stacked in such a way that the first extension region and the second extension region are disposed at identical positions in plan view, and the fin of the first heat radiating plate and the fin of the second heat radiating plate are disposed at identical positions in plan view.

2. (canceled)

3. The heat radiating device according to claim 1, wherein: a pitch of the fin are substantially identical with each other.

4. The heat radiating device according to claim 1, wherein: the pitch of the fin is smaller than a thickness of the heat radiator.

5. The heat radiating device according to claim 1, wherein;
each of the plurality of heat radiating plates includes
a first region including a gravity center,
a plurality of second regions extending radially from the first region in the in-plane direction toward the periphery, and
a third region around the first region and the plurality of second regions;
the fin having a comb shape is located at the third region; and
at least one of the plurality of heat radiating plates includes
on a front surface, a first fitting section formed in at least one of the plurality of second regions, and
on a rear surface, a second fitting section formed in at least one of the plurality of second regions, the second fitting section having a shape so as to fit with the first fitting section.

6. The heat radiating device according to claim 5, wherein:
a plurality of the first fitting sections are formed, toward the periphery on the front surface in the plurality of second regions;
a plurality of the second fitting sections are formed, toward the periphery on the rear surface in the plurality of second regions, and
the plurality of first fitting sections of first one of the at least one of the plurality of heat radiating plates fit with the plurality of second fitting sections formed on the rear surface of second one of the at least one of the plurality of radiating plates, the second one of the at least one of the plurality of heat radiating plates being disposed on a side of the front surface of the first one of the at least one of the plurality of heat radiating plates.

7. The heat radiating device according to claim 6, wherein:
the plurality of first fitting sections and the plurality of second fitting sections are fitted by caulking.

8. The heat radiating device according to claim 1, further comprising:
a frame housing the fan, the frame being provided on the surface of the heat radiator, the surface being opposite to the other surface where the heating element is located, wherein
a gap having a size identical to the pitch of the fin is formed between the frame and the heat radiator.

9. The heat radiating device according to claim 8, wherein:
the gap is a gap between a lower end of the frame and an upper surface of the heat radiator.

10. The heat radiating device according to claim 1, wherein:
a part of the plurality of heat radiating plates is formed of a material different from rest of the plurality of heat radiating plates.
